(19) United States
(12) Patent Application Publication
(10) Pub. No.: US 2025/0308881 A1
(43) Pub. Date: Oct. 2, 2025

(54) SILICON ETCH BYPRODUCT REMOVAL

(71) Applicant: Applied Materials, Inc., Santa Clara, CA (US)

(72) Inventors: Sonam Dorje SHERPA, Santa Clara, CA (US); Han Soo CHO, San Jose, CA (US); Alok RANJAN, Santa Clara, CA (US)

(21) Appl. No.: 18/619,083

(22) Filed: Mar. 27, 2024

(51) Int. Cl. H01L 21/02; H01J 37/32; H01L 21/308

(52) U.S. Cl. CPC H01L 21/02057; H01J 37/32449; H01L 21/308; H01J 2237/2007; H01J 2237/3341

(57) ABSTRACT

Embodiments of the disclosure include apparatus which includes a substrate disposed on a substrate support within a substrate processing chamber. A surface of the substrate has a layer of byproduct from a silicon etching process. A reactive layer is formed in the layer of byproduct by injecting hydrogen fluoride into the substrate processing chamber and maintaining a temperature of the substrate support at less than 0 degrees Celsius. The hydrogen fluoride is purged from the substrate processing chamber by flowing argon into the substrate processing chamber. A plasma is generated by ionizing the argon. A portion of the layer of byproduct is removed from the surface of the substrate by using the plasma for desorption of the reactive layer.

### BACKGROUND

### Field

Embodiments described herein generally relate to a system and methods for removing etching byproduct. More specifically, embodiments of the present disclosure relate to silicon etch byproduct removal.

### Description of the Related Art

In general, the objective in silicon etching processes such as those used in semiconductor manufacturing is to etch features that are deep and narrow (e.g., with high aspect ratios) having uniform sidewalls that are straight, smooth, and parallel. Achieving this objective is challenging because of redeposition in which byproducts generated during an etching process are redeposited onto a substrate surface. Redeposition of the byproducts can cause clogging of etched features, ion and neutral shadowing, formation of undesirable layers or coatings on sidewalls of the etched features, etc. There are some techniques for removing the byproduct from the substrate surface such as fluorine-based flashes; however, these techniques lack selectivity to silicon and controllability. Because of the uncontrollability of conventional byproduct removal techniques, silicon underlying the byproduct is also removed resulting in a loss of profile control.

Accordingly, there is a need in the art for a desirable byproduct removal technique that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide an apparatus that includes a substrate disposed on a substrate support within a substrate processing chamber. A surface of the substrate has a layer of byproduct from a silicon etching process. The apparatus includes a non-transitory computer readable medium storing executable instructions that, when executed by at least one processor, cause a byproduct removal from the surface of the substrate by operations including forming a reactive layer in the layer of byproduct by injecting hydrogen fluoride into the substrate processing chamber and maintaining a temperature of the substrate support at less than 0 degrees Celsius. The hydrogen fluoride is purged from the substrate processing chamber by flowing argon into the substrate processing chamber. A plasma is generated by ionizing the argon. A portion of the layer of byproduct is removed from the surface of the substrate by using the plasma for desorption of the reactive layer.

Embodiments of the present disclosure provide a substrate processing chamber that includes a substrate and a layer of byproduct from a silicon etching process disposed on a surface of the substrate. A hydrogen fluoride delivery system is configured to inject hydrogen fluoride into the substrate processing chamber and form a reactive layer in the layer of byproduct. A processing gas delivery system is configured to purge the hydrogen fluoride from the substrate processing chamber by flowing a processing gas into the substrate processing chamber. An electrode is configured to receive a pulsed voltage waveform and generate a plasma using the processing gas. The plasma is configured to remove a portion of the layer of byproduct from the surface of the substrate by desorption of the reactive layer.

Embodiments of the present disclosure provide a method including performing a silicon etching process on a substrate disposed within a substrate processing chamber. A reactive layer is formed in a layer of byproduct from the silicon etching process using physisorption of hydrogen fluoride. The layer of byproduct is disposed on a surface of the substrate. Argon is flowed into the substrate processing chamber to purge the hydrogen fluoride from the substrate processing chamber. A plasma is generated within the substrate processing chamber using the argon. A portion of the layer of byproduct is removed from the surface of the substrate by using the plasma for desorption of the reactive layer.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic representation of an example substrate processing system, in accordance with certain embodiments of the present disclosure.

FIG. 1B illustrates a representation of a surface of a substrate without a layer of byproduct compared with a representation of the surface of the substrate with the layer of byproduct, in accordance with certain embodiments of the present disclosure.

FIG. 2 illustrates a graph of inputs for removing a portion of a layer of byproduct from a surface of a substrate, in accordance with certain embodiments of the present disclosure.

FIG. 3 illustrates a representation of a substrate at various stages of a process for removing a portion of a layer of byproduct from a surface of the substrate, in accordance with certain embodiments of the present disclosure.

FIG. 4 illustrates examples of a substrate having different amounts of a layer of byproduct removed from a surface of the substrate, in accordance with certain embodiments of the present disclosure.

FIG. 5 is a flow diagram illustrating a method for removing a portion of a layer of byproduct from a surface of a substrate, in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to apparatus and methods for removing etching byproduct. More specifically, embodiments described herein provide for silicon etch byproduct removal. In some embodiments, a substrate is disposed on a substrate support in a substrate processing chamber, and a temperature of the substrate support is maintained at below 0 degrees Celsius. A layer of byproduct from a silicon etching process is disposed over a surface of the substrate. In various embodiments, the layer of byproduct includes one or more silicon-based materials such as silicon oxide, SiOBr, SiOCl, etc.

A hydrogen fluoride delivery system is coupled to the substrate processing chamber, and the hydrogen fluoride delivery system injects hydrogen fluoride (e.g., hydrogen fluoride vapor) into the substrate processing chamber. In one or more embodiments, the hydrogen fluoride is physisorbed on a surface of the layer of byproduct at the temperature below 0 degrees Celsius (e.g., of the substrate support). In some embodiments, the physisorbed hydrogen fluoride then diffuses into the layer of byproduct to form a reactive layer in the layer of byproduct.

A gas delivery system is coupled to the substrate processing chamber. In various embodiments, the gas delivery system purges the hydrogen fluoride from the substrate processing chamber by flowing a processing gas into the substrate processing chamber. In some embodiments, the processing gas is argon. In certain embodiments, a plasma is generated in the substrate processing chamber by ionizing the argon. In one or more embodiments, the argon plasma is generated by an electric filed induced in the substrate processing chamber by a voltage source, by a source radio frequency (RF) generator, or by both the voltage source and the source RF generator.

In some embodiments, ions of the argon plasma bombard the reactive layer. In various embodiments, a portion of the layer of byproduct is removed from the surface of the substrate by desorption of the reactive layer using the ions of the argon plasma. In certain embodiments, a thickness of the portion of the layer of byproduct is controllably adjustable in a range of less than one nanometer to 100 nanometers. Because of this controllability, the layer of byproduct can be removed without removing a portion of the underlying substrate. Conventional techniques for byproduct removal such as fluorine-based flashes often remove portions of the underlying substrate because of a lack of such controllability resulting in a loss of profile control.

### Processing System Examples

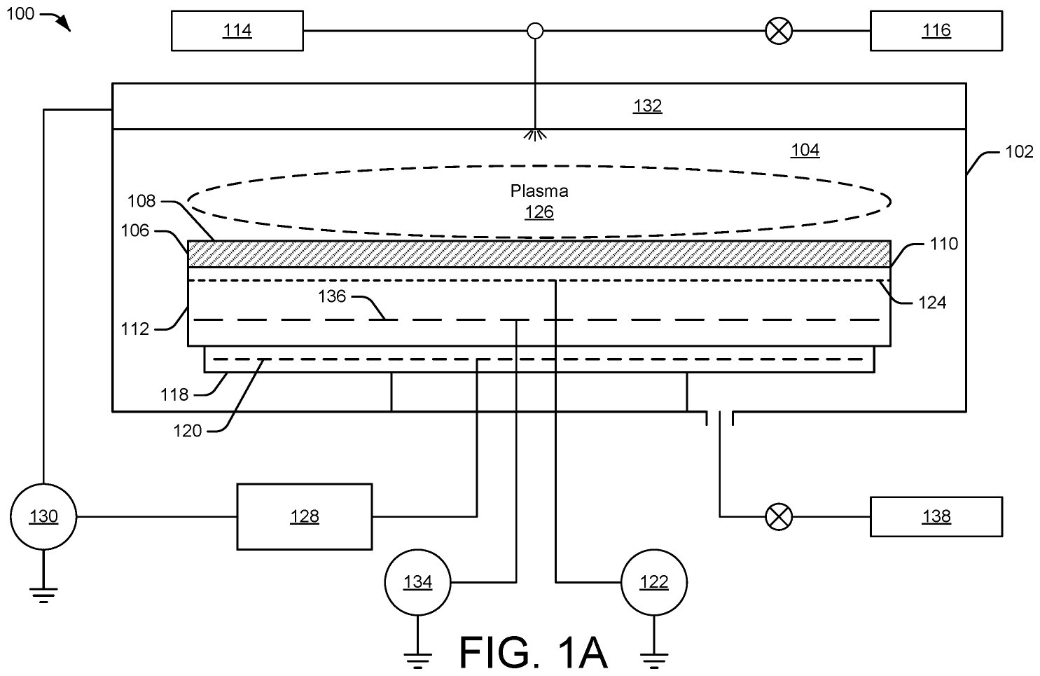

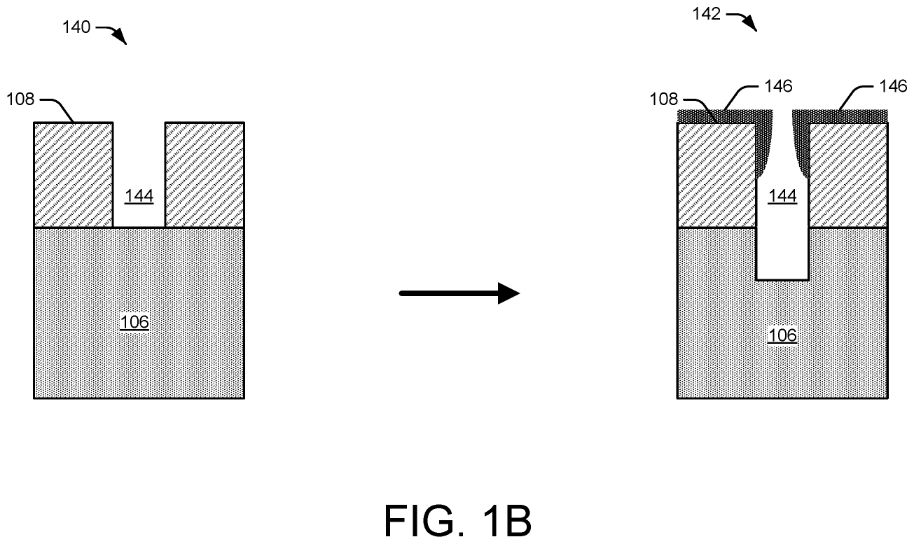

FIG. 1A is a schematic representation of an example substrate processing system 100. The substrate processing system 100 is representative of a variety of different systems such as etching chambers (including plasma-assisted systems and non-plasma-assisted systems) and other similar processing systems or chambers. The substrate processing system 100 is illustrated to include a substrate processing chamber 102 which contains a processing region 104.

A substrate support 112 is included in the processing region 104. The substrate support 112 supports a substrate 106 during processing. The substrate 106 has a surface 108, and a layer of silicon etching byproduct is disposed on the surface 108. In some embodiments, at least a portion of the substrate 106 includes silicon and the layer of silicon etching byproduct is from a silicon etching process (e.g., a silicon etching process) performed on the substrate 106. In other embodiments, the layer of silicon etching byproduct is from a different source such as a silicon etching process performed on another substrate within the processing chamber 102. In various embodiments, the layer of silicon etching byproduct includes silicon-based material. Examples of silicon based materials include silicon oxide, SiOBr, SiOCl, etc.

In the illustrated example, the substrate processing system 100 includes a hydrogen fluoride delivery system 114 configured to inject hydrogen fluoride (e.g., hydrogen fluoride vapor) into the substrate processing chamber 102. In certain embodiments, the hydrogen fluoride delivery system 114 is configured to inject hydrogen fluoride into the substrate processing chamber 102 at a flow rate in a range of 100 to 1000 standard cubic centimeters per minute (sccm) such as a flow rate of 280 sccm. In some examples, the hydrogen fluoride delivery system 114 is configured to inject hydrogen fluoride into the substrate processing chamber 102 at a flow rate less than 100 sccm or greater than 1000 sccm.

In one or more embodiments, injecting hydrogen fluoride into the substrate processing chamber 102 may cause hydrogen fluoride diffusion into the surface 108 of the substrate 106. In some embodiments, the hydrogen fluoride is physisorbed on a surface of the layer of byproduct that includes the silicon-based material, and then the hydrogen fluoride diffuses into the layer of byproduct. In certain embodiments, the hydrogen fluoride diffusion may be configured to form a reactive layer (e.g., by hydrogen fluoride physisorption, hydrogen fluoride chemisorption, etc.) in the layer of byproduct. Notably, a thickness of the reactive layer is adjustable to increase or decrease a thickness of the layer of byproduct to be removed. In some embodiments, the thickness of the reactive layer may be adjusted by increasing/decreasing a time for the hydrogen fluoride diffusion, increasing/decreasing a pressure within the substrate processing chamber 102, etc.

In various embodiments, the thickness of the reactive layer is adjustable in a range of less than one nanometer to 100 nanometers. In some examples, a temperature of the substrate 106 or a pressure within the substrate processing chamber 102 may be adjusted to vary the thickness of the reactive layer. The temperature of the substrate 106 is generally controlled by controlling the temperature of the surface 110 of the substrate support 112. In one or more embodiments, a temperature of the surface 110 of the substrate support 112 may be less than zero degrees Celsius. In certain embodiments, the pressure within the substrate processing chamber 102 may be in a range of 25 mTorr to 30 mTorr such as 27 mTorr. In some embodiments, the pressure within the substrate processing chamber 102 can be less than 25 mTorr or greater than 30 m Torr.

In various embodiments, after forming the reactive layer on the layer of byproduct disposed on the surface 108 of the substrate 106, the hydrogen fluoride is purged from the substrate processing chamber 102, for example, by displacing the hydrogen fluoride with a processing gas. A gas delivery system 116 is coupled to the processing region 104 of the substrate processing chamber 102. The gas delivery system 116 is configured to deliver at least one processing gas (e.g., argon, nitrogen, helium, etc.) to the processing region 104. In some embodiments, the gas delivery system 116 is configured to flow the processing gas into the substrate processing chamber 102 in order to purge the hydrogen fluoride from the substrate processing chamber 102. In one or more embodiments, the gas delivery system 116 flows argon into the substrate processing chamber 102 which purges the hydrogen fluoride from the substrate processing chamber 102.

In the illustrated example, the substrate support 112 includes a printed circuit board (PCB) 118. In some embodiments, a circuit layer 120 of the PCB 118 includes transistors (e.g., MOSFETs) configured as switches. The transistors included in the circuit layer 120 can be controlled to open or close electrical connections such as an electrical connection between a voltage source 122 and a chucking electrode 124. As shown, the chucking electrode 124 is disposed in the substrate support 112 near the surface 110. In one or more embodiments, closing the electrical connection between the voltage source 122 and the chucking electrode 124 causes the voltage source 122 to deliver a pulsed voltage (PV) waveform to the chucking electrode 124.

In some examples, delivering the PV waveform to the chucking electrode 124 generates an electric field within the substrate processing chamber 102 which is filled with the argon. Electrons of the electric field are accelerated (e.g., by pulses of the PV waveform) and become high-energy electrons. Some of the high-energy electrons collide with neutral atoms/molecules of the argon with sufficient energy to overcome binding energy of electrons of the neutral atoms/molecules which causes the neutral atoms/molecules to lose one or more electrons and become positively charged ions. The lost electrons are now free electrons and a plasma 126 forms as the combination of the neutral argon atoms/molecules, the positively charged ions, and the free electrons.

The substrate processing system 100 includes a controller 128 electrically coupled to the circuit layer 120 of the PCB 118. The controller 128 is also electrically coupled to a source radio frequency (RF) generator 130. In one or more embodiments, the controller 128 includes a computing device having one or more processors, support circuits, and memory. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The controller 128 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile. The controller 128 is used to control the operation of the processing system 100, such as, performing for removing a portion of a layer of byproduct from a surface of a substrate, as further described below.

The source RF generator 130 is electrically coupled to an electrode 132 which is disposed above the substrate support 112 of the substrate processing chamber 102. In some examples, the electrode 132 is a plate for capacitively coupling power to gases present the processing region 104 above the substrate 106 supported on the substrate support 112. In other examples, the electrode 132 is one or more coils for inductively coupling power to gases present the processing region 104 above the substrate 106 supported on the substrate support 112. In some embodiments, RF power supplied to the electrode 132 by the source RF generator 130 is also capable of generating the plasma 126 by ionizing the argon within the substrate processing chamber 102. In certain embodiments, the voltage source 122 supplies the PV waveform to the chucking electrode 124 and the source RF generator 130 supplies the RF power to the electrode 132 in order to control the plasma 126 by optimizing one or more properties of the plasma 126. Although not shown, there is a matching circuit disposed between the source RF generator 130 and the electrode 132.

In one or more embodiments, the substrate processing system 100 includes a bias RF generator 134 electrically connected to a bias electrode 136 disposed in the substrate support 112. In some embodiments, the bias RF generator 134 may apply an RF bias to the bias electrode 136 which can be used for tuning characteristics of the plasma 126 such as ion energy distribution, plasma density, ion flux, etc. In various embodiments, the source RF generator 130 and/or the voltage source 122 may be also be used for tuning the characteristics of the plasma 126.

In some embodiments, the substrate processing system 100 includes a vacuum source 138 in communication with the processing region 104 through an exhaust port (not shown) disposed through the substrate processing chamber 102. In various embodiments, the vacuum source 138 is configured to generate vacuum pressure to control a pressure within the substrate processing chamber 102. In certain embodiments, the vacuum source 138 may be configured to generate vacuum pressure to purge the hydrogen fluoride and/or the argon from the substrate processing chamber 102. The vacuum source 138 includes one or more vacuum pumps and throttle valves that enable generation and control of vacuum pressure within the substrate processing chamber 102 and removal of process byproducts and unused processing gases.

In various embodiments, the plasma 126 is configured to remove a portion of the layer of byproduct on the surface 108 of the substrate 106 from the silicon etching process via desorption of the reactive layer formed in the layer of byproduct. In some embodiments, as the positively charged ions of the plasma 126 bombard the surface 108 of the substrate 106, the positively charged ions dislodge atoms or molecules of the reactive layer and the portion of the layer of byproduct. Unlike conventional techniques for removing the layer of byproduct such as such as fluorine-based flashes which lack controllability, using the plasma 126 for desorption of the reactive layer is selective and controllable such that a thickness of the portion of the layer of the byproduct may be less than one nanometer. Accordingly, the portion of the layer of the byproduct can be removed using the plasma 126 without damaging the underlying substrate 106 which is often unintentionally damaged using the conventional techniques.

FIG. 1B illustrates a representation 140 of a surface of a substrate without a layer of byproduct compared to a representation 142 of the surface of the substrate with the layer of byproduct. The representation 140 depicts the surface 108 of the substrate 106 in which a feature 144 has been etched. In the representation 142, a layer of byproduct 146 is disposed over the surface 108 of the substrate 106. In some embodiments, a silicon etching process is performed on the representation 140 in order to increase a depth of the feature 144. The increased depth of the feature 144 is illustrated in the representation 142, and byproducts generated by the silicon etching process have redeposited on the surface 108 as the layer of byproduct 146. Because of the layer of byproduct 146 an additional silicon etching process performed to further increase the depth of the feature 144 would yield undesirable results due to etch rate variation, etch profile distortion, etc. For example, sidewalls of the feature 144 may become rough and/or non-parallel.

### Byproduct Removal Examples

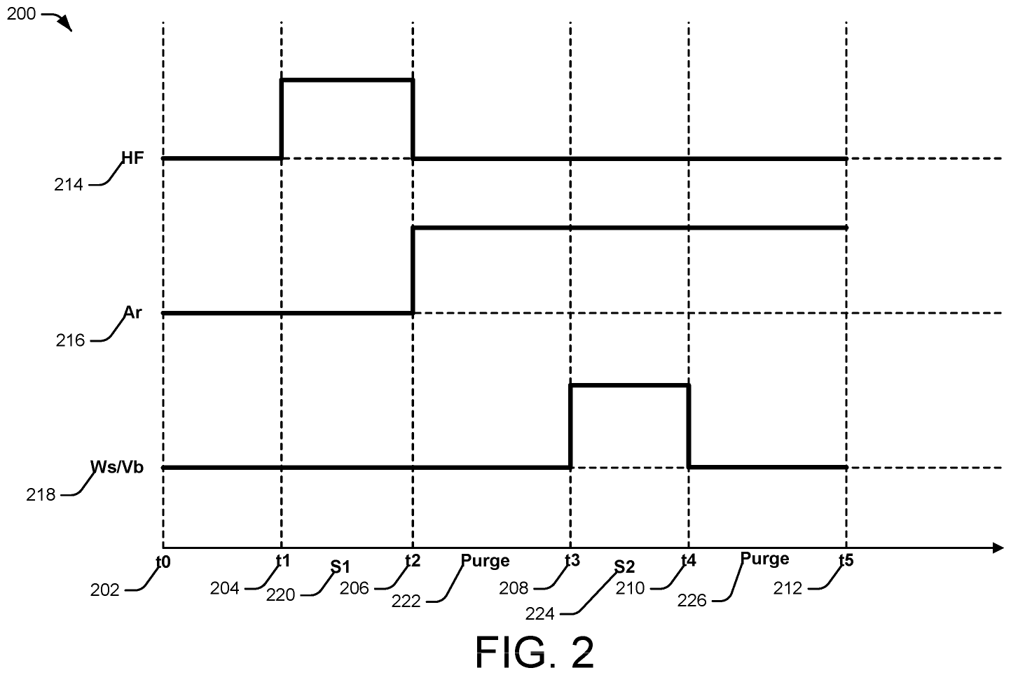

FIG. 2 illustrates a graph 200 of inputs illustrated over time while removing a portion of a layer of byproduct from a surface of a substrate. An x-axis of the graph 200 represents time, and includes a first period of time 202, a second period of time 204, a third period of time 206, a fourth period of time 208, a fifth period of time 210, and a sixth period of time 212. A y-axis of the graph 200 illustrates the amplitude of various input and includes a hydrogen fluoride input 214, an argon input 216, and a power/voltage input 218. The x-axis is also illustrated to include a first period 220, a first purge 222, a second period 224, and a second purge 226. The first period 220 occurs between the second period of time 204 and the third period of time 206; the first purge 222 occurs between the third period of time 206 and the fourth period of time 208; the second period 224 occurs between the fourth period of time 208 and the fifth period of time 210; and the second purge 226 occurs between the fifth period of time 210 and the sixth period of time 212. In some embodiments, the first period 220, the first purge 222, the second period 224, and the second purge 226 collectively form one cycle of silicon etch byproduct removal. In these embodiments, each cycle of silicon etch byproduct removal is configured to remove a portion of the layer of byproduct 146 and a thickness of the portion is adjustable in a range of less than one nanometer to 100 nanometers (or more).

As shown in the graph 200, from the first period of time 202 to the second period of time 204, the hydrogen fluoride input 214 is off (e.g., the hydrogen fluoride delivery system 114 does not inject hydrogen fluoride into the substrate processing chamber 102). From the first period of time 202 to the second period of time 204, the argon input 216 is off (e.g., the gas delivery system 116 does not flow argon into the substrate processing chamber 102). Similarly, from the first period of time 202 to the second period of time 204, power/voltage input 218 is off (e.g., the voltage source 122 does not deliver a pulsed voltage (PV) waveform to the chucking electrode 124, the source radio frequency (RF) generator 130 does not supply RF power to the electrode 132, and the bias RF generator 134 does not apply an RF bias to the bias electrode 136).

From the second period of time 204 to the third period of time 206 (e.g., during the first period 220), the argon input 216 is off and the power/voltage input 218 is off. However, from the second period of time 204 to the third period of time 206, the hydrogen fluoride input 214 is on and the hydrogen fluoride delivery system 114 injects hydrogen fluoride into the substrate processing chamber 102. In some embodiments, the hydrogen fluoride is physisorbed on a surface of the layer of byproduct, and the physisorbed hydrogen fluoride diffuses into the layer of byproduct 146 to form the reactive layer. In certain embodiments, the hydrogen fluoride may form the reactive layer via physisorption in which molecules of the hydrogen fluoride are adsorbed into the surface 108 of the substrate 106. In one or more embodiments, the hydrogen fluoride can form the reactive layer via chemisorption in which molecules of the hydrogen fluoride form chemical bonds with molecules of silicon included in the layer of byproduct 146. In various embodiments, the hydrogen fluoride may form the reactive layer in the layer of byproduct 146 via a combination of physisorption and chemisorption.

In some embodiments, a duration of the first period 220 (e.g., an amount of time between the second period of time 204 and the third period of time 206) can be increased to increase a thickness of the reactive layer or decreased to decrease the thickness of the reactive layer. In one or more embodiments, the duration of the first period 220 may be in a range of 1 second to 60 seconds such as 30 seconds, 35.25 seconds, etc. In various embodiments, the duration of the first period 220 may be less than 1 second or greater than 60 seconds.

From the third period of time 206 to the fourth period of time 208 (e.g., during the first purge 222), the hydrogen fluoride input 214 is off and the power/voltage input 218 is off. During the first purge 222, the argon input 216 is on and the gas delivery system 116 flows argon into the substrate processing chamber 102. In various embodiments, flowing the argon into the substrate processing chamber 102 is configured to purge the hydrogen fluoride from the substrate processing chamber 102. In some embodiments, the vacuum source 138 maybe configured to increase or decrease a pressure within the substrate processing chamber 102 in order to facilitate purging the hydrogen fluoride from the substrate processing chamber 102.

In one or more embodiments, a duration of the first purge 222 may be longer than the duration of the first period 220. In certain embodiments, the duration of the first purge 222 may be in a range of 30 seconds to 180 seconds such as 120 seconds. In various embodiments, the duration of the first purge 222 can be less than 30 seconds or greater than 180 seconds. In some embodiments, during the first purge 222, the gas delivery system 116 flows the argon into the substrate processing chamber 102 at a rate in a range of 100 to 1000 standard cubic centimeters per minute (sccm) such as a rate of 280 sccm. In other embodiments, the gas delivery system 116 flows the argon into the substrate processing chamber 102 at a rate of less than 100 sccm or greater than 1000 sccm. In certain embodiments, the gas delivery system 116 flows the argon into the substrate processing chamber 102 during the first purge 222 at the same rate that the hydrogen fluoride delivery system 114 injects the hydrogen fluoride into the substrate processing chamber 102 during the first period 220. In various embodiments, the gas delivery system 116 flows the argon into the substrate processing chamber 102 during the first purge 222 at a greater rate than the rate that the hydrogen fluoride delivery system 114 injects the hydrogen fluoride into the substrate processing chamber 102 during the first period 220.

From the fourth period of time 208 to the fifth period of time 210 (e.g., during the second period 224), the hydrogen fluoride input 214 is off. As shown in the graph 200, during the second period 224, the argon input 216 is on and the power/voltage input 218 is on. In one or more embodiments, the gas delivery system 116 flows the argon into the substrate processing chamber 102 which is purged of the hydrogen fluoride. In some embodiments, the voltage source 122 delivers the PV waveform to the chucking electrode 124 which ionizes the argon within the processing region 104 and generates the plasma 126. In various embodiments, the source RF generator 130 supplies the RF power to the electrode 132 in order to generate, maintain, and/or control the plasma 126. The plasma 126 is formed as a combination of neutral argon atoms/molecules, positively charged ions, and free electrons.

In certain embodiments, during the second period 224 the voltage source 122 delivers the PV waveform to the chucking electrode 124 and the source RF generator 130 supplies the RF power to the electrode 132. In some embodiments, the bias RF generator 134 may apply the RF bias to the bias electrode 136 which can be used for tuning characteristics of the plasma 126 during the second period 224. In one or more examples, the bias RF generator 134 delivers the RF power to the electrode 132 in order to control energy of the positively charged ions reaching the surface 108 of the substrate 106, enhance directionality of ion bombardment, control a voltage applied to the substrate 106, etc.

In some embodiments, the plasma 126 is configured to remove a portion of the layer of byproduct 146 disposed on the surface 108 of the substrate 106 via desorption of the reactive layer formed in the layer of byproduct 146. In various embodiments, after forming the plasma 126, the positively charged ions included in the plasma 126 are accelerated towards the surface 108 by an electric field generated within the processing region 104 by the voltage source 122, the source RF generator 130, and/or the bias RF generator 134. In one or more embodiments, the accelerated ions collide with the reactive layer formed in the layer of byproduct 146 with a sufficient amount of energy (e.g., kinetic energy) to dislodge particles of the reactive layer and/or the layer of byproduct 146 from the substrate 106. The dislodged particles of the reactive layer and/or the layer of byproduct 146 are ejected (e.g., sputtered) into the processing region 104 and are no longer disposed on the surface 108 of the substrate 106. In various embodiments, the process of bombarding the surface 108 with the ions of the plasma 126 is generally selective such that there is a greater probability of a particle being ejected from the reactive layer and/or the layer of byproduct 146 than from the underlying substrate 106 (e.g., underlying silicon).

In some embodiments, a duration of the second period 224 may be shorter than the duration of the first period 220. In one or more embodiments, the duration of the second period 224 may be in a range of 5 seconds to 30 seconds such as 10 seconds. In various embodiments, the duration of the second period 224 can be less than 5 seconds or greater than 30 seconds.

From the fifth period of time 210 to the sixth period of time 212 (e.g., during the second purge 226), the hydrogen fluoride input 214 is off and the power/voltage input 218 is off. During the second purge 226, the argon input 216 is on and the gas delivery system 116 flows the argon into the substrate processing chamber 102. In some embodiments, flowing the argon into the substrate processing chamber 102 during the second purge 226 is configured to purge particles of the reactive layer and/or the layer of byproduct 146 sputtered off the substrate 106 during the second period 224 from the substrate processing chamber 102.

In various embodiments, during the second purge 226, the gas delivery system 116 flows the argon into the substrate processing chamber 102 at a rate in a range of 100 to 1000 sccm such as 280 sccm. In one or more embodiments, the gas delivery system 116 may flow the argon into the substrate processing chamber 102 at a rate of less than 100 sccm or greater than 1000 sccm. In certain embodiments, a duration of the second purge 226 may be in a range of 20 seconds to 40 seconds such as 30 seconds. In some embodiments, the duration of the second purge 226 can be less than 20 seconds or greater than 40 seconds.

In certain embodiments, after the second purge 226, the substrate processing system 100 may perform an additional cycle for removing an additional portion of the layer of byproduct 146 from the substrate 106. For example, the additional cycle may begin at the first period of time 202 and end at the sixth period of time 212. In some embodiments, after the additional cycle, a silicon etching may be performed or another additional cycle for removing another additional portion of the layer of byproduct 146 can be performed.

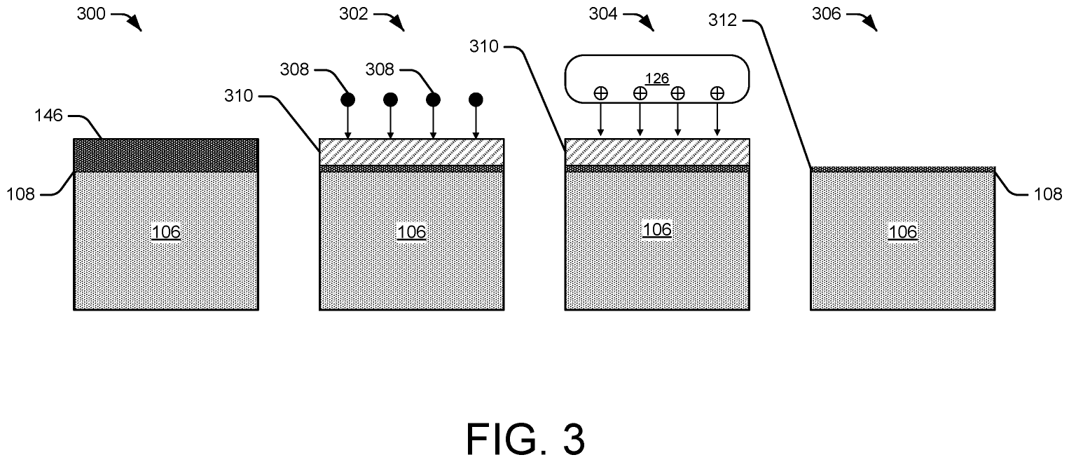

FIG. 3 illustrates a representation of a substrate at various stages of a process for removing a portion of a layer of byproduct from a surface of the substrate. The representation depicted in FIG. 3 includes a first stage 300, a second stage 302, a third stage 304, and a fourth stage 306. In the first stage 300, the layer of byproduct 146 is disposed over the surface 108 of the substrate 106. In some embodiments, the first stage 300 illustrates the substrate 106 after a silicon etching process in which generated byproduct has redeposited on the surface 108 as the layer of byproduct 146.

In the second stage 302, the hydrogen fluoride input 214 is on and the hydrogen fluoride delivery system 114 injects hydrogen fluoride vapor 308 into the substrate processing chamber 102. In one or more embodiments, the hydrogen fluoride vapor 308 diffuses into the layer of byproduct 146 (e.g., after physisorption on a surface of the layer of byproduct 146) and forms a reactive layer 310 (e.g., a non-volatile reactive layer) within a portion of the layer of byproduct 146. In the third stage 304, the argon input 216 is on and the power/voltage input 218 is on which generates the plasma 126.

In some embodiments, the voltage source 122 delivers the pulsed voltage (PV) waveform to the chucking electrode 124 which generates an electric field that causes the ions of the plasma to bombard the reactive layer 310 in a direction that is approximately normal to the reactive layer 310. In one or more embodiments, the directionality of the ion bombardment ensures that the reactive layer 310 and the portion of the layer of byproduct 146 are uniformly removed by desorption of the reactive layer 310. In the fourth stage 306, the reactive layer 310 and the portion of the layer of byproduct 146 are removed. As shown in FIG. 3, removing the portion of the layer of byproduct 146 forms a mask 312 on the surface 108 of the substrate 106 for performing an additional silicon etching process.

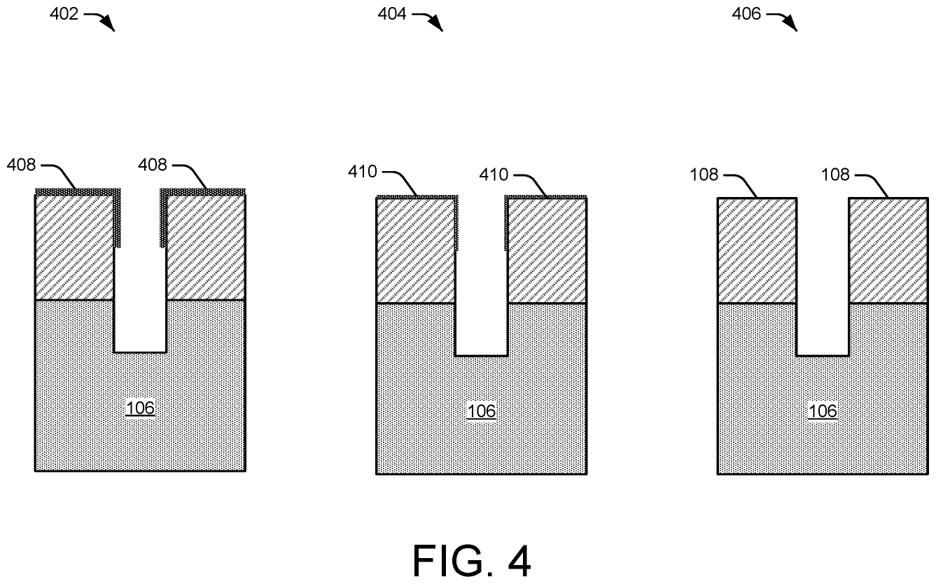

FIG. 4 illustrates examples of a substrate having different amounts of a layer of byproduct removed from a surface of a substrate. As shown, the examples include a first example 402, a second example 404, and a third example 406. In the first example 402, a first layer of byproduct 408 on the surface 108 of the substrate 106 has a first thickness (e.g., two nanometers). In the second example 404, after one cycle of the first stage 300, the second stage 302, the third stage 304, and the fourth stage 306, a second layer of byproduct 410 on the surface 108 of the substrate 106 has a second thickness (e.g., one nanometer). In various embodiments, the second layer of byproduct 410 is included in the first layer of byproduct 408 and the second thickness is less than the first thickness (e.g., one nanometer less). In the third example 406, after one more cycle of the first stage 300, the second stage 302, the third stage 304, and the fourth stage 306, the second layer of byproduct 410 is removed from the surface 108 of the substrate 106. In one or more embodiments, in the third example 406, no portion of the substrate 106 has been removed.

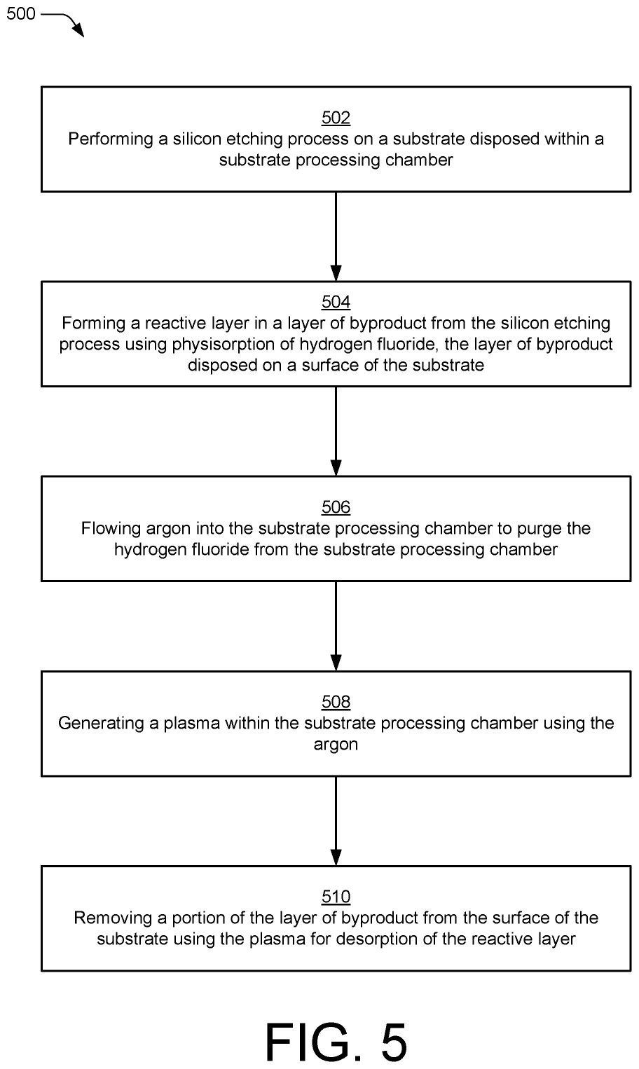

FIG. 5 is a flow diagram illustrating a method 500 for removing a portion of a layer of byproduct from a surface of a substrate. At operation 502, a silicon etching process is performed on a substrate disposed within a substrate processing chamber. In some embodiments, a silicon etching process is performed on the substrate 106 disposed in the substrate processing chamber 102.

At operation 504, a reactive layer is formed in a layer of byproduct from the silicon etching process using physisorption of hydrogen fluoride, the layer of byproduct disposed on a surface of the substrate. In one or more embodiments, the hydrogen fluoride vapor 308 diffuses into the layer of byproduct 146 (e.g., after physisorption on a surface of the layer of byproduct 146) to form the reactive layer 310. At operation 506, argon is flowed into the substrate processing chamber to purge the hydrogen fluoride from the substrate processing chamber. In various embodiments, the hydrogen fluoride vapor 308 is purged from the substrate processing chamber 102 by the argon during the first purge 222.

At operation 508, a plasma is generated in the substrate processing chamber using the argon. In some embodiments, the plasma 126 is formed within the substrate processing chamber 102 by ionizing the argon using the voltage source 122 and/or the source radio frequency (RF) generator 130. At operation 510, a portion of the layer of byproduct is removed from the surface of the substrate using the plasma for desorption of the reactive layer. In one or more embodiments, the portion of the layer of byproduct 146 is removed from the surface 108 of the substrate 106 using the plasma 126 for desorption of the reactive layer 310.

### ADDITIONAL CONSIDERATIONS

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or processes described with respect to one implementation may be combined with the features, components, and/or processes described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more operations or actions for achieving the described method. The method operations and/or actions may be interchanged with one another without departing from the scope of the claims. In other words, unless a specific order of operations or actions is specified, the order and/or use of specific operations and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. An apparatus comprising:
a substrate disposed on a substrate support within a substrate processing chamber, a surface of the substrate having a layer of byproduct from a silicon etching process;
a non-transitory computer readable medium storing executable instructions that, when executed by at least one processor, cause a byproduct removal from the surface of the substrate by operations comprising:
forming a reactive layer in the layer of byproduct by injecting hydrogen fluoride into the substrate processing chamber and maintaining a temperature of the substrate support at less than 0 degrees Celsius;
purging the hydrogen fluoride from the substrate processing chamber by flowing argon into the substrate processing chamber;
generating a plasma within the substrate processing chamber by ionizing the argon; and
removing a portion of the layer of byproduct from the surface of the substrate by using the plasma for desorption of the reactive layer.

2. The apparatus of claim 1, wherein the plasma is generated using at least one of a voltage source or a source radio frequency (RF) generator.

3. The apparatus of claim 2, wherein the plasma is controlled using both the voltage source and the source RF generator.

4. The apparatus of claim 1, wherein a thickness of the portion of the layer of byproduct is less than one nanometer.

5. The apparatus of claim 1, wherein the operations further comprise performing an additional silicon etching process.

6. The apparatus of claim 5, wherein the operations further comprise removing an additional portion of the layer of byproduct from the surface of the substrate, the additional portion from the additional silicon etching process.

7. The apparatus of claim 1, wherein the layer of byproduct includes at least one of silicon oxide, SiOBr, or SiOCl.

8. The apparatus of claim 1, wherein a flow rate of the hydrogen fluoride into the substrate processing chamber is in a range of 100 to 1000 standard cubic centimeters per minute (sccm).

9. The apparatus of claim 1, wherein a thickness of the portion of the layer of byproduct is adjustable in a range of less than one nanometer to 100 nanometers.

10. The apparatus of claim 1, wherein removing the portion of the layer of byproduct from the surface of the substrate is configured to form a mask on the surface of the substrate for an additional silicon etching process.

11. A substrate processing chamber comprising:
a substrate;
a layer of byproduct from a silicon etching process disposed on a surface of the substrate;
a hydrogen fluoride delivery system configured to inject hydrogen fluoride into the substrate processing chamber and form a reactive layer in the layer of byproduct;
a processing gas delivery system configured to purge the hydrogen fluoride from the substrate processing chamber by flowing a processing gas into the substrate processing chamber; and
an electrode configured to receive a pulsed voltage waveform and generate a plasma using the processing gas, the plasma configured to remove a portion of the layer of byproduct from the surface of the substrate by desorption of the reactive layer.

12. The substrate processing chamber of claim 11, wherein the processing gas includes argon.

13. The substrate processing chamber of claim 11, wherein the plasma is controlled using a source radio frequency (RF) generator.

14. The substrate processing chamber of claim 11, wherein the electrode includes a chucking electrode.

15. The substrate processing chamber of claim 11, wherein a thickness of the portion of the layer of byproduct is adjustable in a range of less than one nanometer to 100 nanometers.

16. A method comprising:
performing a silicon etching process on a substrate disposed within a substrate processing chamber;
forming a reactive layer in a layer of byproduct from the silicon etching process using physisorption of hydrogen fluoride, the layer of byproduct disposed on a surface of the substrate;
flowing argon into the substrate processing chamber to purge the hydrogen fluoride from the substrate processing chamber;
generating a plasma within the substrate processing chamber using the argon; and
removing a portion of the layer of byproduct from the surface of the substrate by using the plasma for desorption of the reactive layer.

17. The method of claim 16, wherein the plasma is generated by applying a bias to an electrode disposed in the substrate processing chamber.

18. The method of claim 16, wherein a thickness of the portion of the layer of by product is less than one nanometer.

19. The method of claim 16, further comprising:
forming a mask on the surface of the substrate by removing the portion of the layer of byproduct from the surface of the substrate; and
performing an additional silicon etching process on the substrate using the mask.

20. The method of claim 16, further comprising:
maintaining a temperature of a substrate support that supports the substrate at less than 0 degrees Celsius.
